(19) United States
(12) Patent Application Publication
(10) Pub. No.: US 2017/0012700 A1
(43) Pub. Date: Jan. 12, 2017

(54) OPTICAL DEVICE

(71) Applicant: SUMITOMO OSAKA CEMENT CO., LTD., Tokyo (JP)

(72) Inventors: Youichi HOSOKAWA, TOKYO (JP); Norikazu MIYAZAKI, TOKYO (JP); Satoshi OIKAWA, TOKYO (JP)

(21) Appl. No.: 15/115,708

(22) PCT Filed: Jan. 26, 2015
(86) PCT No.: PCT/JP2015/052069

§ 371 Date: Aug. 1, 2016

(30) Foreign Application Priority Data
Jan. 31, 2014 (JP) 2014-016981

(51) Int. Cl. H04B 10/079; H04B 10/071; H01L 31/16

(52) U.S. Cl. CPC H04B 10/079; H01L 31/165; H04B 10/071

(57) ABSTRACT

An optical device includes a light element that outputs first output light and second output light, a first light-receiving portion that converts the first output light into a first electrical signal, a second light-receiving portion that converts the second output light into a second electrical signal, a substrate having a plurality of surfaces, a first electrode which is provided on the substrate and is connected to the first light-receiving portion, and a second electrode which is provided on the substrate and is connected to the second light-receiving portion, and a part of the first electrode is disposed on a surface different from a surface on which the second electrode is disposed.

### TECHNICAL FIELD

The present invention relates to a optical device.

### BACKGROUND ART

In optical devices such as optical modulators, in order to monitor the operation state of optical devices, constitutions in which some of signal light is branched and monitored and constitutions in which radiation light generated in Y-junction, Y-branch couplers of light such as Mach-Zehnder interferometers is monitored are used. For example, FIGS. 2 and 4 of Patent Literature No. 1 disclose a constitution in which radiation light generated from light Y-junction, Y-branch couplers such as a plurality of Mach-Zehnder interferometers is monitored. Radiation light received using a light-receiving element such as a photo diode (PD) is converted into electrical signals, and the converted electrical signals are output from output pins and the like attached to an optical device through electrical lines provided on a wiring substrate. In addition, the output electrical signals are used as monitoring signals and the like for feedback control of the operation points and the like of optical modulation portions.

### CITATION LIST

### Patent Literature

[Patent Literature No. 1] Japanese Laid-open Patent Publication No. 2004-117605

### SUMMARY OF INVENTION

### Technical Problem

In recent years, in order to deal with large-capacity communication such as 40 Gbps and 100 Gbps, integrated optical modulators corresponding to multi-level modulation formats and polarization-combining schemes have become the mainstream. These optical modulators have a plurality of modulation portions in one modulator. For example, differential quadrature phase shift keying (DQPSK)-type optical modulators have two modulation portions. Dual Polarization-Quadrature Phase Shift Keying (DP-QPSK)-type optical modulators that polarization-combine two different QPSK signals have a structure in which two sub Mach-Zehnder waveguides are disposed in each of the two main Mach-Zehnder waveguides and thus have a total of four modulation portions.

Since the number of light-receiving elements for monitoring signal light or radiation light also increases as the number of modulation portions increases, the installation area of light-receiving elements increases. In addition, the number of electrical lines for connecting electrical signals output from light-receiving elements through output pins also increases, and thus the installation area of wiring substrates provided with electrical lines also increases, and the size of optical devices increases. Furthermore, in recent years, as one of methods for branching and monitoring a part of signal light, the frequency of portion of signal light spectrum (from 0.1 GHz to several GHz) also have been monitored, and the frequencies of monitoring signals have become higher. In addition, in monitoring methods in which dither signals are superimposed on signal light and then the signal light is monitored as well, dither frequency have become higher.

However, on the other hand, there is a demand for size reduction in optical modulators. Therefore, it is not possible to increase the installation area of wiring substrates, and thus there are cases in which it is not possible to ensure the sufficient distances between signal electrodes. As a result of an increase in the number of light-receiving elements as described above, in wiring substrates including a plurality of signal electrodes, there is a concern that crosstalk may be caused between signal electrodes in a case in which it is not possible to ensure the sufficient distance between the signal electrodes.

The present invention provides a optical device which suppresses an increase in the installation area of wiring substrates and has a structure capable of reducing crosstalk between electrodes.

### Solution to Problem

A optical device according to an aspect of the present invention includes a light element that outputs first output light and second output light, a first light-receiving portion that converts the first output light into a first electrical signal, a second light-receiving portion that converts the second output light into a second electrical signal, a substrate having a plurality of surfaces, a first electrode which is provided on the substrate and is connected to the first light-receiving portion, and a second electrode which is provided on the substrate and is connected to the second light-receiving portion. A part of the first electrode is disposed on a surface different from a surface on which the second electrode is disposed.

According to this optical device, a part of the first electrode connected to the first light-receiving portion is disposed on, among the surfaces of the substrate, a surface different from a surface on which the second electrode connected to the second light-receiving portion is disposed. Therefore, compared with a case in which the first electrode and the second electrode are disposed on the same surface of the substrate, it is possible to increase the distance between the first electrode and the second electrode without enlarging the substrate. As a result, it becomes possible to suppress an increase in the installation area of the substrate and reduce crosstalk between the first electrode and the second electrode. Here, for example, any of modulated light, radiation light, and monitoring light of optical modulation elements can be considered as the first output light and the second output light.

A optical device according to another aspect of the present invention may further include a first electrode group which includes the first electrode and includes electrodes that are respectively connected to the first light-receiving portion and a second electrode group which includes the second electrode and includes electrodes that are respectively connected to the second light-receiving portion. A part of the first electrode group may be disposed on a surface different from a surface on which the second electrode group is disposed. In this case, a part of the first electrode group connected to the first light-receiving portion is disposed on, out of the surfaces of the substrate, a surface different from the surface on which the second electrode group connected to the second light-receiving portion is disposed. Therefore, compared with a case in which the first electrode group and the second electrode group are disposed on the same surface of the substrate, it is possible to increase the distance between the first electrode group and the second electrode group without enlarging the substrate. As a result, it becomes possible to suppress an increase in the installation area of the substrate and reduce crosstalk between the first electrode group and the second electrode group.

A optical device according to still another aspect of the present invention may further include a third light-receiving portion that converts third output light into a third electrical signal and a third electrode group in which electrodes are respectively connected to the third light-receiving portion. The light element may further output the third output light, and a part of the first electrode group, a part of the second electrode group, and a part of the third electrode group may be disposed on mutually different surfaces. In this case, apart of the first electrode group connected to the first light-receiving portion, a part of the second electrode group connected to the second light-receiving portion, and a part of the third electrode group connected to the third light-receiving portion are disposed on mutually different surfaces out of a plurality of the surfaces of the substrate. Therefore, compared with a case in which the first electrode group, the second electrode group, and the third electrode group are disposed on the same surface of the substrate, it is possible to increase the distance between the first electrode group, the second electrode group, and the third electrode group without enlarging the substrate. As a result, it becomes possible to suppress an increase in the installation area of the substrate and reduce crosstalk between the first electrode group, the second electrode group, and the third electrode group.

In the optical device according to still another aspect of the present invention, the first electrode group may further include a third electrode, and a part of the first electrode and a part of the third electrode may be disposed side by side to each other. Here, “being side by side” refers to a state in which one electrode is disposed along the other electrode and means not only a state in which two electrodes are parallel to each other but also a state in which two electrodes are not parallel to each other within the scope of the characteristics of the present invention. In this case, it is possible to suppress unnecessary electric field emission and the coupling of signals between electrodes by placing electrode lines for the light-receiving elements in parallel. Therefore, it is possible to reduce the deterioration of the high-frequency characteristics of electrical signals propagating through the first electrode and the third electrode.

In the optical device according to still another aspect of the present invention, the first light-receiving portion and the second light-receiving portion may be provided on the same surface out of a plurality of the surfaces of the substrate. In this case, it is possible to facilitate optical alignment for receiving the first output light and the second output light which are output from the light element.

The optical device according to still another aspect of the present invention may further include a ground electrode which is disposed between the first electrode and the second electrode. In this case, it is possible to orient some of lines of electric force which are oriented from one electrode group to the other electrode group toward the ground electrode by disposing the ground electrode between the first electrode and the second electrode. Therefore, the superimposition of electromagnetic fields between electrodes adjacent to each other becomes slight, and it becomes possible to further reduce crosstalk between the first electrode and the second electrode.

### Advantageous Effects of Invention

According to the present invention, it is possible to suppress an increase in the installation area of wiring substrates and reduce crosstalk between electrodes.

### BRIEF DESCRIPTION OF DRAWINGS

FIG. 1 is a plan view schematically illustrating a constitution of a optical device according to a first embodiment.

FIG. 2 is an enlarged plan view schematically illustrating a part of the optical device of FIG. 1.

FIG. 3 is a perspective view schematically illustrating a constitution example of a monitoring portion in FIG. 1.

FIG. 4 is a perspective view schematically illustrating another constitution example of the monitoring portion in FIG. 1.

FIG. 5 is a perspective view schematically illustrating still another constitution example of the monitoring portion in FIG. 1.

FIG. 6 is a perspective view schematically illustrating still another constitution example of the monitoring portion in FIG. 1.

FIG. 7 is a perspective view schematically illustrating still another constitution example of the monitoring portion in FIG. 1.

FIG. 8 is a perspective view schematically illustrating still another constitution example of the monitoring portion in FIG. 1.

FIG. 9 is an enlarged plan view schematically illustrating a part of an optical device according to a second embodiment.

FIG. 10 is an enlarged plan view schematically illustrating a part of an optical device according to a third embodiment.

FIG. 11 is a side view of the optical device of FIG. 10.

FIG. 12 is a perspective view schematically illustrating a constitution example of a monitoring portion in FIG. 10.

### DESCRIPTION OF EMBODIMENTS

Hereinafter, embodiments of the present invention will be described in detail with reference to the accompanying drawings.

### First Embodiment

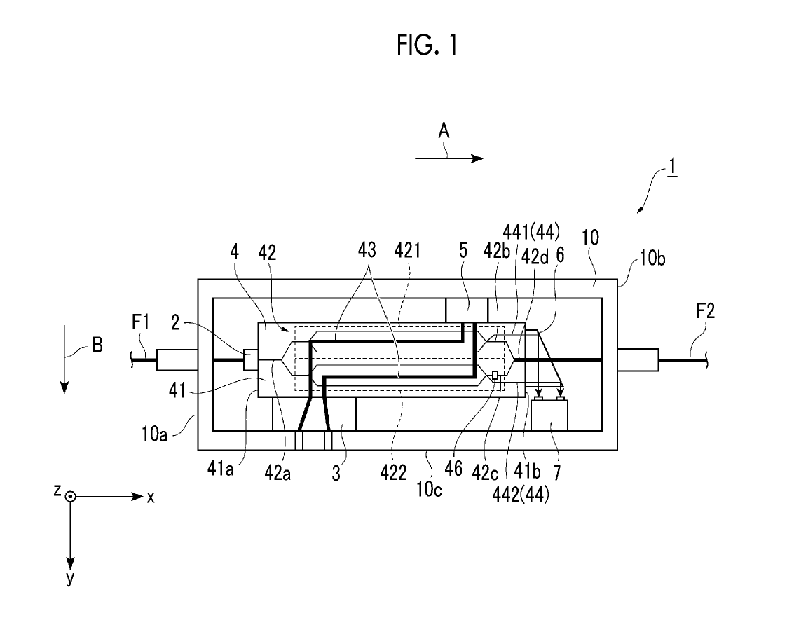

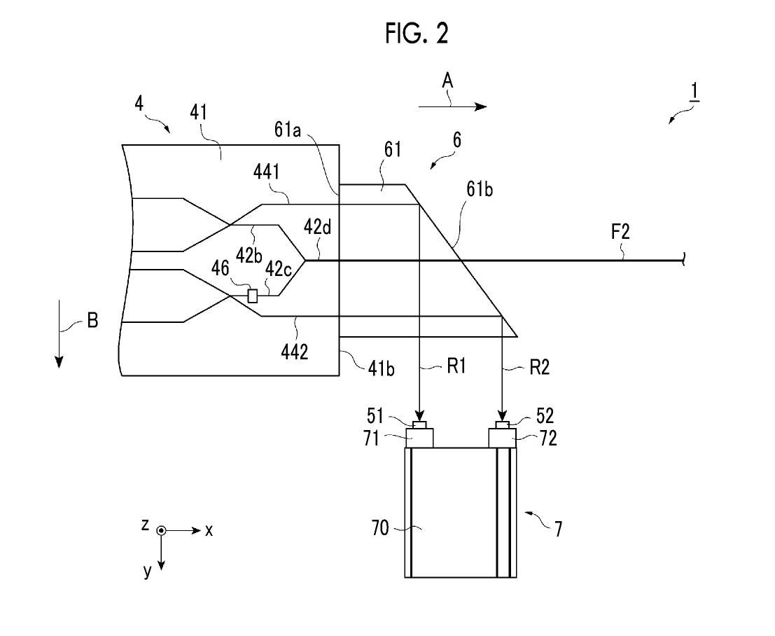

FIG. 1 is a plan view schematically illustrating the constitution of an optical device according to a first embodiment. FIG. 2 is an enlarged plan view schematically illustrating a part of the optical device of FIG. 1. As illustrated in FIGS. 1 and 2, an optical device 1 is an optical modulator that modulates input light introduced using an optical fiber F1 and outputs modulated light to an optical fiber F2. The optical device 1 may include a light input portion 2, a relay portion 3, an optical modulation element 4 (light element), a terminal portion 5, a light output portion 6, a monitoring portion 7, and a package case 10.

The package case 10 is a box-shaped member extending in a single direction (hereinafter, refer to as the “direction A”) and is constituted of, for example, stainless steel. The package case 10 has one end surface 10a and the other end surface 10b which are both end surfaces in the direction A. On the end surface 10a, an opening for inserting the optical fiber F1 is provided. On the end surface 10b, an opening for inserting the optical fiber F2 is provided. The package case 10 is made up of a bottom portion and a lid portion and stores, for example, the light input portion 2, the relay portion 3, the optical modulation element 4, the terminal portion 5, the light output portion 6, and the monitoring portion 7. Here, the direction A is along the x-axis direction of the orthogonal coordinate system, and a direction B perpendicular to the direction A is along the y-axis direction of the orthogonal coordinate system. In the following description, the up, down, front, back, of the optical device 1 refers to the lid portion side of the package case 10, the bottom portion side of the package case 10, a side on which the optical fiber F1 is disposed, and a side on which the optical fiber F2 is disposed.

The light input portion 2 supplies input light introduced using the optical fiber F1 to the optical modulation element 4. The light input portion 2 may include a supplemental member for supplementing the connection between the optical fiber F1 and the optical modulation element 4.

The relay portion 3 relays and outputs modulation signals which are electrical signals supplied from the outside to the optical modulation element 4. The relay portion 3 inputs modulation signals, for example, through a connector for inputting modulation signals which is provided on a side surface 10c of the package case 10 and outputs modulation signals to the optical modulation element 4.

The optical modulation element 4 is an element that converts input light supplied from the light input portion 2 into modulated light in accordance with modulation signals output from the relay portion 3. The optical modulation element 4 may include a substrate 41 and signal electrodes 43. The substrate 41 is constituted of, for example, a dielectric material exhibiting an electro-optic effect such as lithium niobate (LiNbO₃, hereinafter, referred to as “LN”). The substrate 41 extends in the direction A and has one end portion 41a and the other end portion 41b which are both end portions in the direction A.

The substrate 41 has an optical waveguide 42. The optical waveguide 42 is, for example, a Mach-Zehnder-type optical waveguide and has a structure in accordance with the modulation method of the optical modulation element 4. In this example, the modulation format of the optical modulation element 4 is a Dual Polarization-Binary Phase Shift Keying (DP-BPSK) format. In this case, the optical waveguide 42 has a structure in which a Mach-Zehnder portion 421 and a Mach-Zehnder portion 422 are provided on two waveguides 42b and 42c. That is, an input waveguide 42a extends in the direction A from the end portion 41a of the substrate 41, is branched, and is connected to an input end of the Mach-Zehnder portion 421 and an input end of the Mach-Zehnder portion 422 respectively. In an output waveguide 42d, the waveguide 42b extending from an output end of the Mach-Zehnder portion 421 and the waveguide 42c extending from an output end of the Mach-Zehnder portion 422 are joined together and extend in the direction A up to the other end portion 41b.

The signal electrodes 43 are members for applying electric fields in accordance with modulation signals to the optical waveguide 42 and are provided on the substrate 41. The disposition and number of the signal electrodes 43 are determined depending on the orientation of the crystal axis of the substrate 41 and the modulation method of the optical modulation element 4. The respective signal electrodes 43 respectively transmit modulation signals output from the relay portion 3.

The substrate 41 further has a radiation optical waveguide 44. The radiation optical waveguide 44 is an optical waveguide for radiation light and includes a radiation optical waveguide 441 and a radiation optical waveguide 442. The radiation optical waveguide 441 extends from the output end of the Mach-Zehnder portion 421 to the other end portion 41b. The radiation optical waveguide 441 guides radiation light R1 (first output light) leaking out from the output end of the Mach-Zehnder portion 421 and outputs the radiation light in the direction A from the other end portion 41b of the optical modulation element 4. The radiation optical waveguide 442 extends from the output end of the Mach-Zehnder portion 422 to the other end portion 41b. The radiation optical waveguide 442 guides radiation light R2 (second output light) leaking out from the output end of the Mach-Zehnder portion 422 and outputs the radiation light in the direction A from the other end portion 41b of the optical modulation element 4. The radiation optical waveguide 441 and the radiation optical waveguide 442 are provided so as to sandwich the waveguide 42b and the waveguide 42c.

The optical modulation element 4 may further include a polarization-rotating portion 46. The polarization-rotating portion 46 is an element that rotates polarized waves 90 degrees and is, for example, a ½ wavelength plate or the like. The polarization-rotating portion 46 is provided on the waveguide 42c extending from the output end of the Mach-Zehnder portion 422.

In the optical modulation element 4, input light input to the optical modulation element 4 from the light input portion 2 is branched and input into the Mach-Zehnder portion 421 and the Mach-Zehnder portion 422 using the input waveguide 42a. The branched input light is respectively modulated in the Mach-Zehnder portion 421 and the Mach-Zehnder portion 422. Modulated light modulated in the Mach-Zehnder portion 421 propagates in the waveguide 42b. Modulated light modulated in the Mach-Zehnder portion 422 propagates in the waveguide 42c, and polarized waves are rotated 90 degrees using the polarization-rotating portion 46. In addition, the modulated light propagating in the waveguide 42b and the modulated light propagating in the waveguide 42c are multiplexed in the output waveguide 42d and is output from the optical modulation element 4.

The terminal portion 5 is an electrical terminal for modulation signals. The terminal portion 5 may include resistors that respectively correspond to the signal electrodes 43 in the optical modulation element 4. One end of each of the resistors is electrically connected to the signal electrode 43 in the optical modulation element 4, and the other end of each of the resistors is connected to a ground potential. The resistance value of each of the resistors is approximately equal to the characteristic impedance of the signal electrode 43 and is, for example, approximately 50Ω.

The light output portion 6 outputs modulated light output from the optical modulation element 4 to the optical fiber F2. The light output portion 6 includes a supplemental member 61. The supplemental member 61 is a member for supplementing the connection between the optical modulation element 4 and the optical fiber F2 and is, for example, a glass capillary. The supplemental member 61 holds the optical fiber F2 so as to optically couple the optical waveguide 42 in the optical modulation element 4 and the optical fiber F2. The optical fiber F2 is joined to the other end portion 41b of the optical modulation element 4 so as to be optically coupled to the output waveguide 42d in the optical waveguide 42. The supplemental member 61 has a joining surface 61a and a reflection surface 61b. The joining surface 61a is joined to the other portion 41b of the substrate 41. The reflection surface 61b is inclined, for example, approximately 45° with respect to the direction A and reflects the radiation light R1 and the radiation R2 which are output from the optical modulation element 4 in the direction B.

The monitoring portion 7 monitors the light intensities of the radiation light R1 and the radiation light R2 which are output from the optical modulation element 4. The monitoring portion 7 receives the radiation light R1 and the radiation light R2 and outputs electrical signals in accordance with the light intensities of the radiation light R1 and the radiation light R2 to a bias control portion (not illustrated) which is an external circuit. Meanwhile, the monitoring portion 7 may monitor the light intensity of branched light of modulated light. This monitoring portion 7 can be provided as a wiring device.

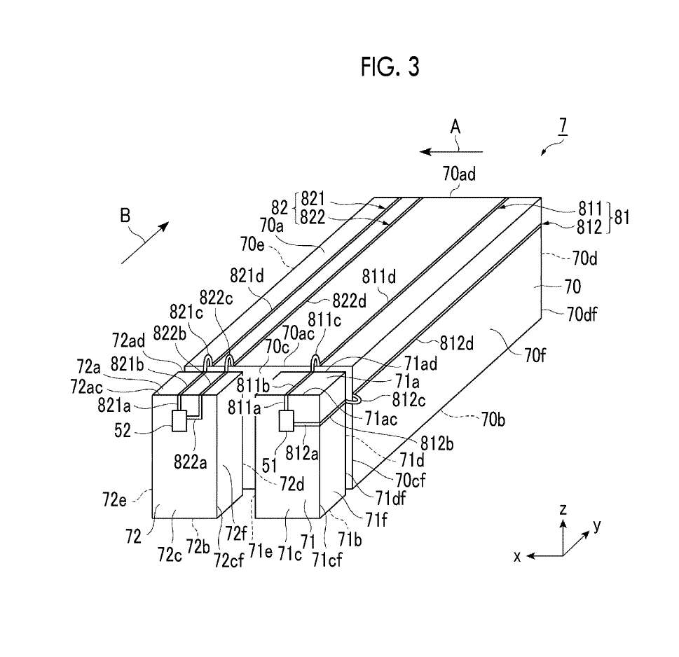

FIG. 3 is a perspective view schematically illustrating a constitution example of the monitoring portion 7. As illustrated in FIG. 3, the monitoring portion 7 is a wiring device and includes a substrate 70, a sub substrate 71, a sub substrate 72, a light-receiving element 51 (first light-receiving portion), a light-receiving element 52 (second light-receiving portion), an electrode group 81 (first electrode group), and an electrode group 82 (second electrode group). Meanwhile, here, a constitution example in which the monitoring portion 7 includes the two sub base bodies 71 and 72 will be described, but the constitution is not limited thereto. The monitoring portion 7 may include one sub substrate or may include three or more sub base bodies. In addition, a plurality of light-receiving elements may be provided in one sub substrate.

The substrate 70 is a polyhedron and have, for example, a quadratic prism shape extending in the direction B. The substrate 70 is constituted of, for example, ceramic such as alumina (Al₂O₃). The height of the substrate 70 is, for example, approximately 1 mm to 5 mm, the length (width) of the substrate 70 in the direction A is, for example, approximately 1 mm to 5 mm, and the length of the substrate 70 in the direction B is, for example, approximately 1 mm to 20 mm.

The substrate 70 has a top surface 70a, a bottom surface 70b, a side surface 70c, a side surface 70d, a side surface 70e, and a side surface 70f. The top surface 70a and the bottom surface 70b, the side surface 70c and the side surface 70d, and the side surface 70e and the side surface 70f face each other and are disposed side by side respectively. The top surface 70a and the bottom surface 70b have, for example, a rectangular shape and are surfaces that are mutually adjacent to each of the side surface 70c, the side surface 70d, the side surface 70e, and the side surface 70f. The side surface 70c, the side surface 70d, the side surface 70e, and the side surface 70f have, for example, a rectangular shape and are disposed in this order along the circumferential edge of the top surface 70a and the circumferential edge of the bottom surface 70b. The substrate 70 is installed in the package case 10 so that the bottom surface 70b faces the bottom portion of the package case 10 and the side surface 70d is located on the side surface 10c side of the package case 10.

The sub substrate 71 has, for example, a quadratic prism shape. The sub substrate 71 is constituted of, for example, ceramic such as alumina (Al₂O₃). The height of the sub substrate 71 is, for example, approximately 1 mm to 5 mm, the length (width) of the sub substrate 71 in the direction A is, for example, approximately 1 mm to 5 mm, and the length of the sub substrate 71 in the direction B is, for example, approximately 1 mm to 5 mm.

The sub substrate 71 has a top surface 71a, a bottom surface 71b, a side surface 71c, a side surface 71d, a side surface 71e, and a side surface 71f. The top surface 71a and the bottom surface 71b, the side surface 71c and the side surface 71d, and the side surface 71e and the side surface 71f face each other and are disposed side by side respectively. The top surface 71a and the bottom surface 71b have, for example, a rectangular shape and are surfaces that are mutually adjacent to each of the side surface 71c, the side surface 71d, the side surface 71e, and the side surface 71f. The side surface 71c, the side surface 71d, the side surface 71e, and the side surface 71f have, for example, a rectangular shape and are disposed in this order along the circumferential edge of the top surface 71a and the circumferential edge of the bottom surface 71b. The sub substrate 71 is installed in the package case 10 so that the bottom surface 71b faces the bottom portion of the package case 10 and the side surface 71d faces the side surface 70c of the substrate 70.

The sub substrate 72 has, for example, a quadratic prism shape. The sub substrate 72 is constituted of, for example, ceramic such as alumina (Al₂O₃). The height of the sub substrate 72 is, for example, approximately 1 mm to 5 mm, the length (width) of the sub substrate 72 in the direction A is, for example, approximately 1 mm to 5 mm, and the length of the sub substrate 72 in the direction B is, for example, approximately 1 mm to 5 mm.

The sub substrate 72 has a top surface 72a, a bottom surface 72b, a side surface 72c, a side surface 72d, a side surface 72e, and a side surface 72f. The top surface 72a and the bottom surface 72b, the side surface 72c and the side surface 72d, and the side surface 72e and the side surface 72f face each other and are disposed side by side respectively. The top surface 72a and the bottom surface 72b have, for example, a rectangular shape and are surfaces that are mutually adjacent to each of the side surface 72c, the side surface 72d, the side surface 72e, and the side surface 72f. The side surface 72c, the side surface 72d, the side surface 72e, and the side surface 72f have, for example, a rectangular shape and are disposed in this order along the circumferential edge of the top surface 72a and the circumferential edge of the bottom surface 72b. The sub substrate 72 is installed in the package case 10 so that the bottom surface 72b faces the bottom portion of the package case 10, the side surface 72d faces the side surface 70c of the substrate 70, and the side surface 72f faces the side surface 71e of the sub substrate 71. The sub substrate 71 and the sub substrate 72 are sequentially arranged in the direction A.

The light-receiving element 51 is an element for converting light signals into electrical signals and is, for example, a photo diode. The light-receiving element 51 is provided on the side surface 71c of the sub substrate 71. The light-receiving element 51 is disposed at a location on the side surface 71c at which the light-receiving element is capable of receiving the radiation light R1 output from the optical modulation element 4. The light-receiving element 51 receives the radiation light R1 and outputs an electrical signal E1 (first electrical signal) in accordance with the intensity of the received radiation light R1 from an anode terminal of the light-receiving element 51. The anode terminal of the light-receiving element 51 is provided toward, for example, a side 71cf which is the boundary between the side surface 71c and the side surface 71f. A cathode terminal of the light-receiving element 51 is provided toward, for example, a side 71ac which is the boundary between the top surface 71a and the side surface 71c.

The light-receiving element 52 is an element for converting light signals into electrical signals and is, for example, a photo diode. The light-receiving element 52 is provided on the side surface 72c of the sub substrate 72. The light-receiving element 52 is disposed at a location on the side surface 72c at which the light-receiving element is capable of receiving the radiation light R2 output from the optical modulation element 4. The light-receiving element 52 receives the radiation light R2 and outputs an electrical signal E2 (second electrical signal) in accordance with the intensity of the received radiation light R2 from an anode terminal of the light-receiving element 52. An anode terminal of the light-receiving element 52 is provided toward, for example, a side 72ac which is the boundary between the top surface 72a and the side surface 72c. A cathode terminal of the light-receiving element 52 is provided toward, for example, a side 72cf which is the boundary between the side surface 72c and the side surface 72f.

The electrode group 81 is a set of a plurality of electrodes that are respectively connected to the light-receiving element 51. The electrode group 81 includes an electrode 811 (third electrode) and an electrode 812 (first electrode). The electrode 811 is an electrode connected to the cathode terminal of the light-receiving element 51 at one end. The electrode 811 is constituted of, for example, a metallic material such as gold (Au), silver (Ag), or copper (Cu). The width of the electrode 811 is, for example, approximately 0.05 mm to 0.5 mm. The electrode 811 is disposed across the side surface 71c of the sub substrate 71, the top surface 71a of the sub substrate 71, and the top surface 70a of the substrate 70 and has a first portion 811a, a second portion 811b, a third portion 811c, and a fourth portion 811d.

The first portion 811a is provided on the side surface 71c of the sub substrate 71 and extends from the cathode terminal of the light-receiving element 51 up to the side 71ac. One end of the first portion 811a is connected to the cathode terminal of the light-receiving element 51. The second portion 811b is provided on the top surface 71a of the sub substrate 71 and extends from the side 71ac up to a side 71ad which is the boundary between the top surface 71a and the side surface 71d. One end of the second portion 811b is connected to the other end of the first portion 811a at the side 71ac. The third portion 811c is a portion at which the other end of the second portion 811b and one end of the fourth portion 811d are connected to each other and is, for example, a wire. The fourth portion 811d is provided on the top surface 70a of the substrate 70 and extends from a side 70ac which is the boundary between the top surface 70a and the side surface 70c to a side 70ad which is the boundary between the top surface 70a and the side surface 70d. The other end of the fourth portion 811d is electrically connected to an external circuit through a wire not illustrated. The electrode 811 constituted as described above supplies certain voltage supplied from the external circuit to the cathode terminal of the light-receiving element 51.

The electrode 812 is an electrode connected to the anode terminal of the light-receiving element 51 at one end. The electrode 812 is constituted of, for example, a metallic material such as gold (Au), silver (Ag), or copper (Cu). The width of the electrode 812 is, for example, approximately 0.05 mm to 0.5 mm. The electrode 812 is disposed across the side surface 71c of the sub substrate 71, the side surface 71f of the sub substrate 71, and the side surface 70f of the substrate 70 and has a first portion 812a, a second portion 812b, a third portion 812c, and a fourth portion 812d.

The first portion 812a is provided on the side surface 71c of the sub substrate 71 and extends from the anode terminal of the light-receiving element 51 up to the side 71cf. One end of the first portion 812a is connected to the anode terminal of the light-receiving element 51. The second portion 812b is provided on the side surface 71f of the sub substrate 71 and extends from the side 71cf up to a side 71df which is the boundary between the side surface 71d and the side surface 71f. One end of the second portion 812b is connected to the other end of the first portion 812a at the side 71cf. The third portion 812c is a portion at which the other end of the second portion 812b and one end of the fourth portion 812d are connected to each other and is, for example, a wire. The fourth portion 812d is provided on the side surface 70f of the substrate 70 and extends from a side 70cf which is the boundary between the side surface 70c and the side surface 70f to a side 70df which is the boundary between the side surface 70d and the side surface 70f. The other end of the fourth portion 812d is electrically connected to an external circuit through a wire not illustrated. The electrode 812 constituted as described above transfers the electrical signal E1 output from the anode terminal of the light-receiving element 51 and outputs the electrical signal to the external circuit through the wire.

The electrode 811 and the electrode 812 are disposed side by side to each other. Specifically, the second portion 811b and the second portion 812b and the fourth portion 811d and the fourth portion 812d respectively extend side by side with each other. The gap between the second portion 811b and the second portion 812b and the gap between the fourth portion 811d and the fourth portion 812d are, for example, approximately 0.15 mm to 0.5 mm.

The electrode group 82 is a set of a plurality of electrodes that are respectively connected to the light-receiving element 52. The electrode group 82 includes an electrode 821 (second electrode) and an electrode 822. The electrode 821 is an electrode connected to the anode terminal of the light-receiving element 52 at one end. The electrode 821 is constituted of, for example, a metallic material such as gold (Au), silver (Ag), or copper (Cu). The width of the electrode 821 is, for example, approximately 0.05 mm to 0.5 mm. The electrode 821 is disposed across the side surface 72c of the sub substrate 72, the top surface 72a of the sub substrate 72, and the top surface 70a of the substrate 70 and has a first portion 821a, a second portion 821b, a third portion 821c, and a fourth portion 821d.

The first portion 821a is provided on the side surface 72c of the sub substrate 72 and extends from the anode terminal of the light-receiving element 52 up to the side 72ac. One end of the first portion 821a is connected to the cathode terminal of the light-receiving element 52. The second portion 821b is provided on the top surface 72a of the sub substrate 72 and extends from the side 72ac up to a side 72ad which is the boundary between the top surface 72a and the side surface 72d. One end of the second portion 821b is connected to the other end of the first portion 821a at the side 72ac. The third portion 821c is a portion at which the other end of the second portion 821b and one end of the fourth portion 821d are connected to each other and is, for example, a wire. The fourth portion 821d is provided on the top surface 70a of the substrate 70 and extends from the side 70ac up to the side 70ad. The other end of the fourth portion 821d is electrically connected to an external circuit through a wire not illustrated. The electrode 821 constituted as described above transfers the electrical signal E2 output from the anode terminal of the light-receiving element 52 and outputs the electrical signal to the external circuit through the wire.

The electrode 822 is an electrode connected to the cathode terminal of the light-receiving element 52 at one end. The electrode 822 is constituted of, for example, a metallic material such as gold (Au), silver (Ag), or copper (Cu). The width of the electrode 822 is, for example, approximately 0.05 mm to 0.5 mm. The electrode 822 is disposed across the side surface 72c of the sub substrate 72, the top surface 72a of the sub substrate 72, and the top surface 70a of the substrate 70 and has a first portion 822a, a second portion 822b, a third portion 822c, and a fourth portion 822d.

The first portion 822a is provided on the side surface 72c of the sub substrate 72 and extends in an L shape from the cathode terminal of the light-receiving element 52 up to the side 72ac. One end of the first portion 822a is connected to the cathode terminal of the light-receiving element 52. The second portion 822b is provided on the top surface 72a of the sub substrate 72 and extends from the side 72ac up to the side 72ad. One end of the second portion 822b is connected to the other end of the first portion 822a at the side 72ac. The third portion 822c is a portion at which the other end of the second portion 822b and one end of the fourth portion 822d are connected to each other and is, for example, a wire. The fourth portion 822d is provided on the top surface 70a of the substrate 70 and extends from the side 70ac up to the side 70ad. The other end of the fourth portion 822d is electrically connected to an external circuit through a wire not illustrated. The electrode 822 constituted as described above supplies certain voltage supplied from the external circuit to the cathode terminal of the light-receiving element 52.

The electrode 821 and the electrode 822 are disposed side by side to each other. Specifically, the first portion 821a and the first portion 822a that extend in direction of up side and down side of the sub substrate 72, the second portion 821b and the second portion 822b, and the fourth portion 821d and the fourth portion 822d respectively extend side by side with each other. The gap between the second portion 821b and the second portion 822b and the gap between the fourth portion 821d and the fourth portion 822d are, for example, approximately 0.15 mm to 0.5 mm.

In the monitoring portion 7 constituted as described above, the light-receiving element 51 is provided in the sub substrate 71, and the light-receiving element 52 is provided in the sub substrate 72. Therefore, a part (the first portion 811a, the second portion 811b, the first portion 812a, and the second portion 812b) of the electrode group 81 connected to the light-receiving element 51 is disposed in a substrate (the sub substrate 71) different from the substrate (the sub substrate 72) in which a part (the first portion 821a, the second portion 821b, the first portion 822a, and the second portion 822b) of the electrode group 82 connected to the light-receiving element 52 is disposed. As a result, it becomes possible to reduce crosstalk between the electrode group 81 and the electrode group 82 without increasing the installation area of the monitoring portion 7.

In addition, in the monitoring portion 7, the fourth portion 811d of the electrode 811, the fourth portion 821d of the electrode 821, and the fourth portion 822d of the electrode 822 are provided on the top surface 70a of the substrate 70, and the fourth portion 812d of the electrode 812 is provided on the side surface 70f of the substrate 70. As described above, when the fourth portion 812d of the electrode 812 in the electrode group 81 is disposed on a surface different from the surface on which the other electrodes are disposed, it is possible to increase the distance between the fourth portion 812d of the electrode 812 and the electrode group 82 without enlarging the substrate 70. Furthermore, the fourth portion 811d of the electrode 811 is disposed on the same top surface 70a as the fourth portion 821d of the electrode 821 and the fourth portion 822d of the electrode 822, but the disposition of the fourth portion 812d of the electrode 812 on the side surface 70f enables an increase in the distance between the fourth portion 811d of the electrode 811 and the electrode group 82 compared with a case in which the fourth portion 812d of the electrode 812 is disposed on the top surface 70a. As a result, it becomes possible to suppress an increase in the installation area of the monitoring portion 7 and reduce crosstalk between the electrode group 81 and the electrode group 82.

In addition, in the monitoring portion 7, the electrode 811 and the electrode 812 and the electrode 821 and the electrode 822 are respectively disposed side by side to each other. In this case, it is possible to suppress unnecessary electric field emission and the coupling of signals between electrodes by placing electrode lines for the light-receiving elements side by side. Therefore, it is possible to reduce the deterioration of the high-frequency characteristics of electrical signals propagating through the electrode 811, the electrode 812, the electrode 821, and the electrode 822.

Meanwhile, the location of the anode terminal and the location of the cathode terminal in the light-receiving element 51 may be switched with each other. In addition, the location of the anode terminal and the location of the cathode terminal in the light-receiving element 52 may be switched with each other. Furthermore, it is also possible to switch the location of the anode terminal and the location of the cathode terminal in the light-receiving element 51 and switch the location of the anode terminal and the location of the cathode terminal in the light-receiving element 52. Even in these cases, similarly, it becomes possible to suppress an increase in the installation area of the monitoring portion 7 and reduce crosstalk between the electrode group 81 and the electrode group 82. In addition, the substrate 70, the sub substrate 71, and the sub substrate 72 are separately configured, but may be integrally configured.

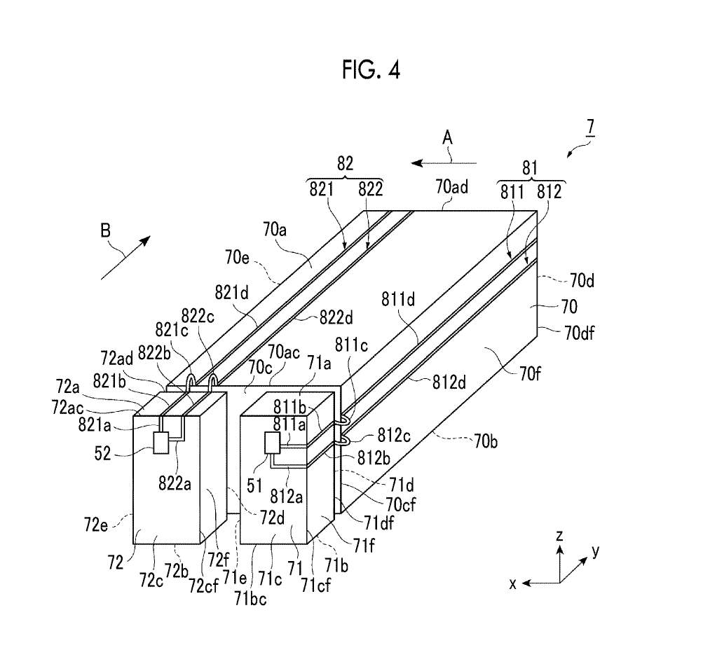

FIG. 4 is a perspective view schematically illustrating another constitution example of the monitoring portion 7. As illustrated in FIG. 4, the monitoring portion 7 is different from the monitoring portion 7 of FIG. 3 in terms of the disposition of the electrode group 81. In the monitoring portion 7 of FIG. 4, the anode terminal of the light-receiving element 51 is provided toward, for example, a side 71bc which is the boundary between the bottom surface 71b and the side surface 71c. The cathode terminal of the light-receiving element 51 is provided toward, for example, the side 71cf.

The electrode 811 is disposed across the side surface 71c of the sub substrate 71, the side surface 71f of the sub substrate 71, and the side surface 70f of the substrate 70 and has the first portion 811a, the second portion 811b, the third portion 811c, and the fourth portion 811d. The first portion 811a is provided on the side surface 71c of the sub substrate 71 and extends from the cathode terminal of the light-receiving element 51 up to the side 71cf. One end of the first portion 811a is connected to the cathode terminal of the light-receiving element 51. The second portion 811b is provided on the side surface 71f of the sub substrate 71 and extends from the side 71cf up to the side 71df. One end of the second portion 811b is connected to the other end of the first portion 811a at the side 71cf. The third portion 811c is a portion at which the other end of the second portion 811b and one end of the fourth portion 811d are connected to each other and is, for example, a wire. The fourth portion 811d is provided on the side surface 70f of the substrate 70 and extends from the side 70cf up to the side 70df. The other end of the fourth portion 811d is electrically connected to an external circuit through a wire not illustrated.

The electrode 812 is disposed across the side surface 71c of the sub substrate 71, the side surface 71f of the sub substrate 71, and the side surface 70f of the substrate 70 and has the first portion 812a, the second portion 812b, the third portion 812c, and the fourth portion 812d. The first portion 812a is provided on the side surface 71c of the sub substrate 71 and extends in an L shape from the anode terminal of the light-receiving element 51 up to the side 71cf. One end of the first portion 812a is connected to the anode terminal of the light-receiving element 51. The second portion 812b is provided on the side surface 71f of the sub substrate 71 and extends from the side 71cf up to the side 71df. One end of the second portion 812b is connected to the other end of the first portion 812a at the side 71cf. The third portion 812c is a portion at which the other end of the second portion 812b and one end of the fourth portion 812d are connected to each other and is, for example, a wire. The fourth portion 812d is provided on the side surface 70f of the substrate 70 and extends from the side 70cf up to the side 70df. The other end of the fourth portion 812d is electrically connected to an external circuit through a wire not illustrated.

The electrode 811 and the electrode 812 are disposed side by side to each other. Specifically, portions of the first portion 811a and the first portion 812a which extend in the direction A, the second portion 811b and the second portion 812b, and the fourth portion 811d and the fourth portion 812d respectively extend in side by side with each other. The gap between the portions of the first portion 811a and the first portion 812a which extend in the direction A, the gap between the second portion 811b and the second portion 812b, and the gap between the fourth portion 811d and the fourth portion 812d are, for example, approximately 0.15 mm to 0.5 mm.

In the monitoring portion 7 of FIG. 4 as well, the same effects as in the monitoring portion 7 of FIG. 3 are exhibited. Furthermore, in the monitoring portion 7 of FIG. 4, the fourth portion 811d of the electrode 811 and the fourth portion 812d of the electrode 812 are provided on the side surface 70f of the substrate 70, and the fourth portion 821d of the electrode 821 and the fourth portion 822d of the electrode 822 are provided on the top surface 70a of the substrate 70. As described above, when a part of the electrode group 81 and a part of the electrode group 82 are disposed on mutually different surfaces, it is possible to increase the distance between the electrode group 81 and the electrode group 82 without enlarging the substrate 70 compared with a case in which the electrode group 81 and the electrode group 82 are disposed on the same surface. As a result, it becomes possible to suppress an increase in the installation area of the monitoring portion 7 and reduce crosstalk between the electrode group 81 and the electrode group 82.

Meanwhile, the location of the anode terminal and the location of the cathode terminal in the light-receiving element 51 may be switched with each other. In addition, the location of the anode terminal and the location of the cathode terminal in the light-receiving element 52 may be switched with each other. Furthermore, it is also possible to switch the location of the anode terminal and the location of the cathode terminal in the light-receiving element 51 and switch the location of the anode terminal and the location of the cathode terminal in the light-receiving element 52. Even in these cases, similarly, it becomes possible to suppress an increase in the installation area of the monitoring portion 7 and reduce crosstalk between the electrode group 81 and the electrode group 82. In addition, the substrate 70, the sub substrate 71, and the sub substrate 72 are separately configured, but may be integrally configured.

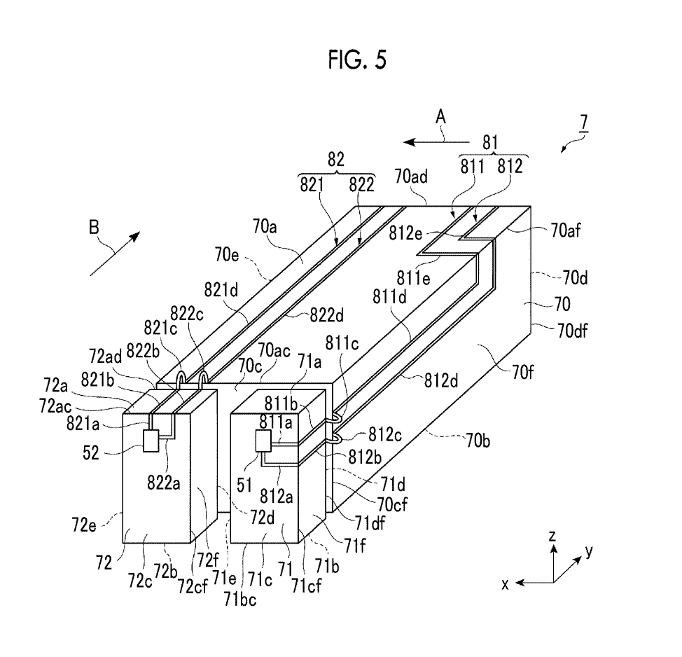

FIG. 5 is a perspective view schematically illustrating still another constitution example of the monitoring portion 7. As illustrated in FIG. 5, the monitoring portion 7 is different from the monitoring portion 7 of FIG. 4 in terms of the disposition of the electrode group 81.

In the monitoring portion 7 of FIG. 5, the electrode 811 is disposed across the side surface 71c of the sub substrate 71, the side surface 71f of the sub substrate 71, the side surface 70f of the substrate 70, and the top surface 70a of the substrate 70 and has the first portion 811a, the second portion 811b, the third portion 811c, the fourth portion 811d, and a fifth portion 811e. The first portion 811a is provided on the side surface 71c of the sub substrate 71 and extends from the cathode terminal of the light-receiving element 51 up to the side 71cf. One end of the first portion 811a is connected to the cathode terminal of the light-receiving element 51. The second portion 811b is provided on the side surface 71f of the sub substrate 71 and extends from the side 71cf up to the side 71df. One end of the second portion 811b is connected to the other end of the first portion 811a at the side 71cf. The third portion 811c is a portion at which the other end of the second portion 811b and one end of the fourth portion 811d are connected to each other and is, for example, a wire. The fourth portion 811d is provided on the side surface 70f of the substrate 70 and extends in an L shape from the side 70cf to a side 70af which is the boundary between the top surface 70a and the side surface 70f. The fifth portion 811e is provided on the top surface 70a of the substrate 70 and extends in an L shape from the side 70af up to the side 70ad. One end of the fifth portion 811e is connected to the other end of the fourth portion 811d at the side 70af. The other end of the fifth portion 811e is electrically connected to an external circuit through a wire not illustrated.

The electrode 812 is disposed across the side surface 71c of the sub substrate 71, the side surface 71f of the sub substrate 71, the side surface 70f of the substrate 70, and the top surface 70a of the substrate 70 and has the first portion 812a, the second portion 812b, the third portion 812c, the fourth portion 812d, and a fifth portion 812e. The first portion 812a is provided on the side surface 71c of the sub substrate 71 and extends in an L shape from the anode terminal of the light-receiving element 51 up to the side 71cf. One end of the first portion 812a is connected to the anode terminal of the light-receiving element 51. The second portion 812b is provided on the side surface 71f of the sub substrate 71 and extends from the side 71cf up to the side 71df. One end of the second portion 812b is connected to the other end of the first portion 812a at the side 71cf. The third portion 812c is a portion at which the other end of the second portion 812b and one end of the fourth portion 812d are connected to each other and is, for example, a wire. The fourth portion 812d is provided on the side surface 70f of the substrate 70 and extends in an L shape from the side 70cf up to the side 70af. The fifth portion 812e is provided on the top surface 70a of the substrate 70 and extends in an L shape from the side 70af up to the side 70ad. One end of the fifth portion 812e is connected to the other end of the fourth portion 812d at the side 70af. The other end of the fifth portion 812e is electrically connected to an external circuit through a wire not illustrated.

The electrode 811 and the electrode 812 are disposed side by side to each other. Specifically, portions of the first portion 811a and the first portion 812a which extend in the direction A, the second portion 811b and the second portion 812b, the fourth portion 811d and the fourth portion 812d, and the fifth portion 811e and the fifth portion 812e respectively extend side by side with each other. The gap between the portions of the first portion 811a and the first portion 812a which extend in the direction A, the gap between the second portion 811b and the second portion 812b, the gap between the fourth portion 811d and the fourth portion 812d, and the gap between the fifth portion 811e and the fifth portion 812e are, for example, approximately 0.15 mm to 0.5 mm.

In the monitoring portion 7 of FIG. 5 as well, the same effects as in the monitoring portion 7 of FIG. 4 are exhibited. Furthermore, in the monitoring portion 7 of FIG. 5, the fifth portion 811e of the electrode 811 and the fifth portion 812e of the electrode 812 are provided on the top surface 70a of the substrate 70. Therefore, it is possible to electrically connect the monitoring portion 7 and external circuits on the same surface (the top surface 70a), and it becomes possible to improve working efficiency such as wire bonding. In addition, since it is possible to simplify wiring between the monitoring portion 7 and external circuits, it becomes possible to reduce the space occupied by electrode lines. The electrode 811 and the electrode 812 may be disposed so that the wire bonding between a portion on the sub substrate 71 and a portion on the substrate 70 is carried out on the top surface 70a of the substrate 70. In this case, the entire wire bonding can be carried out on the same surface (the top surface 70a) of the substrate 70, and it becomes possible to further improve working efficiency.

Meanwhile, the location of the anode terminal and the location of the cathode terminal in the light-receiving element 51 may be switched with each other. In addition, the location of the anode terminal and the location of the cathode terminal in the light-receiving element 52 may be switched with each other. Furthermore, it is also possible to switch the location of the anode terminal and the location of the cathode terminal in the light-receiving element 51 and switch the location of the anode terminal and the location of the cathode terminal in the light-receiving element 52. Even in these cases, similarly, it becomes possible to suppress an increase in the installation area of the monitoring portion 7 and reduce crosstalk between the electrode group 81 and the electrode group 82. In addition, the substrate 70, the sub substrate 71, and the sub substrate 72 are separately configured, but may be integrally configured.

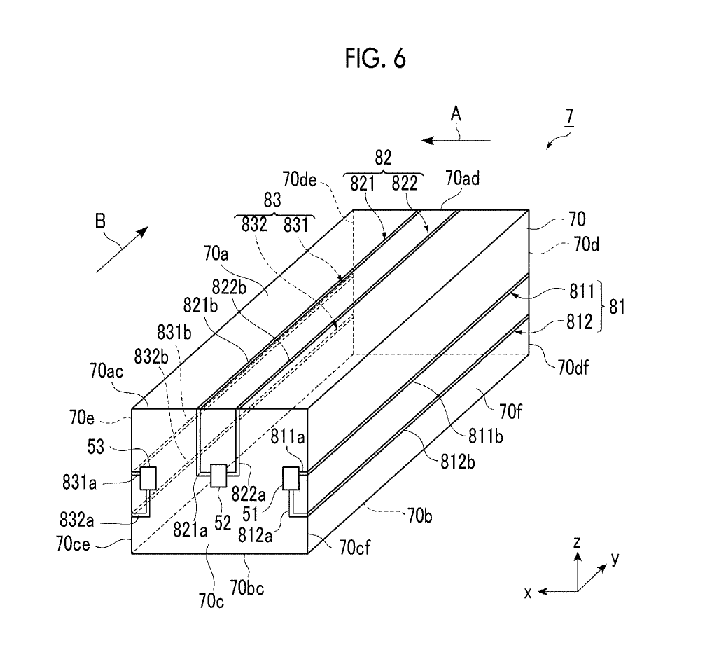

FIG. 6 is a perspective view schematically illustrating still another constitution example of the monitoring portion 7. As illustrated in FIG. 6, the monitoring portion 7 is different from the monitoring portion 7 of FIG. 4 in terms of the additional inclusion of a light-receiving element 53 (third light-receiving portion) and an electrode group 83 (third electrode group) and the absence of the sub substrate 71 and the sub substrate 72. The monitoring portion 7 of FIG. 6 is used in a case in which the optical modulation element 4 further outputs radiation light R3 (third output light). The light-receiving element 53 is an element for converting light signals into electrical signals and is, for example, a photo diode. The light-receiving element 53 receives the radiation light R3 and outputs an electrical signal E3 (third electrical signal) in accordance with the intensity of the received radiation light R3 from an anode terminal of the light-receiving element 53.

The light-receiving element 51, the light-receiving element 52, and the light-receiving element 53 are provided on the side surface 70c of the substrate 70, and are arranged in the direction A in an order of the light-receiving element 51, the light-receiving element 52, and the light-receiving element 53. The light-receiving element 51, the light-receiving element 52, and the light-receiving element 53 are respectively disposed at locations on the side surface 70c at which the light-receiving elements are capable of receiving the radiation light R1, the radiation light R2, and the radiation light R3 which are output from the optical modulation element 4. The anode terminal of the light-receiving element 51 is provided toward, for example, a side 70bc which is the boundary between the bottom surface 70b and the side surface 70c. The cathode terminal of the light-receiving element 51 is provided toward, for example, the side 70cf. The anode terminal of the light-receiving element 52 is provided toward, for example, a side 70ce which is the boundary between the side surface 70c and the side surface 70e. The cathode terminal of the light-receiving element 52 is provided toward, for example, the side 70cf. An anode terminal of the light-receiving element 53 is provided toward, for example, the side 70bc. A cathode terminal of the light-receiving element 53 is provided toward, for example, the side 70ce.

The electrode 811 is disposed across the side surface 70c and the side surface 70f of the substrate 70 and has the first portion 811a and the second portion 811b. The first portion 811a is provided on the side surface 70c of the substrate 70 and extends from the cathode terminal of the light-receiving element 51 up to the side 70cf. One end of the first portion 811a is connected to the cathode terminal of the light-receiving element 51. The second portion 811b is provided on the side surface 70f of the substrate 70 and extends from the side 70cf up to the side 70df. One end of the second portion 811b is connected to the other end of the first portion 811a at the side 70cf. The other end of the second portion 811b is electrically connected to an external circuit through a wire not illustrated.

The electrode 812 is disposed across the side surface 70c and the side surface 70f of the substrate 70 and has the first portion 812a and the second portion 812b. The first portion 812a is provided on the side surface 70c of the substrate 70 and extends in an L shape from the anode terminal of the light-receiving element 51 up to the side 70cf. One end of the first portion 812a is connected to the anode terminal of the light-receiving element 51. The second portion 812b is provided on the side surface 70f of the substrate 70 and extends from the side 70cf up to the side 70df. One end of the second portion 812b is connected to the other end of the first portion 812a at the side 70cf. The other end of the second portion 812b is electrically connected to an external circuit through a wire not illustrated.

The electrode 811 and the electrode 812 are disposed side by side to each other. Specifically, portions of the first portion 811a and the first portion 812a which extend in the direction A and the second portion 811b and the second portion 812b respectively extend side by side with each other. The gap between the portions of the first portion 811a and the first portion 812a which extend in the direction A and the gap between the second portion 811b and the second portion 812b are, for example, approximately 0.15 mm to 0.5 mm.

The electrode 821 is disposed across the side surface 70c and the top surface 70a of the substrate 70 and has the first portion 821a and the second portion 821b. The first portion 821a is provided on the side surface 70c of the substrate 70 and extends in an L shape from the anode terminal of the light-receiving element 52 up to the side 70ac. One end of the first portion 821a is connected to the anode terminal of the light-receiving element 52. The second portion 821b is provided on the top surface 70a of the substrate 70 and extends from the side 70ac up to the side 70ad. One end of the second portion 821b is connected to the other end of the first portion 821a at the side 70ac. The other end of the second portion 821b is electrically connected to an external circuit through a wire not illustrated.

The electrode 822 is disposed across the side surface 70c and the top surface 70a of the substrate 70 and has the first portion 822a and the second portion 822b. The first portion 822a is provided on the side surface 70c of the substrate 70 and extends in an L shape from the cathode terminal of the light-receiving element 52 up to the side 70ac. One end of the first portion 822a is connected to the cathode terminal of the light-receiving element 52. The second portion 822b is provided on the top surface 70a of the substrate 70 and extends from the side 70ac up to the side 70ad. One end of the second portion 822b is connected to the other end of the first portion 822a at the side 70ac. The other end of the second portion 822b is electrically connected to an external circuit through a wire not illustrated.

The electrode 821 and the electrode 822 are disposed side by side to each other. Specifically, a portion of the first portion 821a which extends in the vertical direction and a portion of the first portion 822a which extend in the vertical direction and the second portion 821b and the second portion 822b respectively extend side by side with each other. The gap between the portion of the first portion 821a which extends in the vertical direction and the portion of the first portion 822a which extend in the vertical direction and the gap between the second portion 821b and the second portion 822b are, for example, approximately 0.15 mm to 0.5 mm.

The electrode group 83 is a set of a plurality of electrodes that are respectively connected to the light-receiving element 53. The electrode group 83 includes an electrode 831 and an electrode 832. The electrode 831 is an electrode connected to the cathode terminal of the light-receiving element 53 at one end. The electrode 831 is constituted of, for example, a metallic material such as gold (Au), silver (Ag), or copper (Cu). The width of the electrode 831 is, for example, approximately 0.05 mm to 0.5 mm. The electrode 831 is disposed across the side surface 70c and the side surface 70e of the substrate 70 and has a first portion 831a and a second portion 831b.

The first portion 831a is provided on the side surface 70c of the substrate 70 and extends from the cathode terminal of the light-receiving element 53 up to the side 70ce. One end of the first portion 831a is connected to the cathode terminal of the light-receiving element 53. The second portion 831b is provided on the side surface 70e of the substrate 70 and extends from the side 70ce to a side 70de which is the boundary between the side surface 70d and the side surface 70e. One end of the second portion 831b is connected to the other end of the first portion 831a at the side 70ce. The other end of the second portion 831b is electrically connected to an external circuit through a wire not illustrated. The electrode 831 constituted as described above supplies certain voltage supplied from the external circuit to the cathode terminal of the light-receiving element 53.

The electrode 832 is an electrode connected to the anode terminal of the light-receiving element 53 at one end. The electrode 832 is constituted of, for example, a metallic material such as gold (Au), silver (Ag), or copper (Cu). The width of the electrode 832 is, for example, approximately 0.05 mm to 0.5 mm. The electrode 832 is disposed across the side surface 70c and the side surface 70e of the substrate 70 and has a first portion 832a and a second portion 832b. The first portion 832a is provided on the side surface 70c of the substrate 70 and extends in an L shape from the anode terminal of the light-receiving element 53 up to the side 70ce. One end of the first portion 832a is connected to the anode terminal of the light-receiving element 53. The second portion 832b is provided on the side surface 70e of the substrate 70 and extends from the side 70ce up to the side 70de. One end of the second portion 832b is connected to the other end of the first portion 832a at the side 70ce. The other end of the second portion 832b is electrically connected to an external circuit through a wire not illustrated. The electrode 832 constituted as described above transfers the electrical signal E3 output from the anode terminal of the light-receiving element 53 and outputs the electrical signal to the external circuit through the wire.

The electrode 831 and the electrode 832 are disposed side by side to each other. Specifically, portions of the first portion 831a and the first portion 832a which extend in the direction A and the second portion 831b and the second portion 832b respectively extend side by side with each other. The gap between the portions of the first portion 831a and the first portion 832a which extend in the direction A and the gap between the second portion 831b and the second portion 832b are, for example, approximately 0.15 mm to 0.5 mm.

In the monitoring portion 7 of FIG. 6, the second portion 811b of the electrode 811 and the second portion 812b of the electrode 812 are provided on the side surface 70f of the substrate 70, the second portion 821b of the electrode 821 and the second portion 822b of the electrode 822 are provided on the top surface 70a of the substrate 70, and the second portion 831b of the electrode 831 and the second portion 832b of the electrode 832 are provided on the side surface 70e of the substrate 70. As described above, when a part of the electrode group 81, a part of the electrode group 82, and a part of the electrode group 83 are disposed on mutually different surfaces, it is possible to increase the mutual distance between the electrode group 81, the electrode group 82, and the electrode group 83 without enlarging the substrate 70 compared with a case in which the electrode group 81, the electrode group 82, and the electrode group 83 are disposed on the same surface. As a result, it becomes possible to suppress an increase in the installation area of the monitoring portion 7 and reduce crosstalk between the electrode group 81, the electrode group 82, and the electrode group 83.

In addition, in the monitoring portion 7 of FIG. 6, the electrode 811 and the electrode 812, the electrode 821 and the electrode 822, and the electrode 831 and the electrode 832 are respectively disposed side by side to each other. In this case, it is possible to suppress unnecessary electric field emission and the coupling of signals between electrodes by placing electrode lines for the light-receiving elements side by side. Therefore, it is possible to reduce the deterioration of the high-frequency characteristics of electrical signals propagating through the electrode 811, the electrode 812, the electrode 821, the electrode 822, the electrode 831, and the electrode 832.

In addition, in the monitoring portion 7 of FIG. 6, the light-receiving element 51, the light-receiving element 52, and the light-receiving element 53 are provided on the same surface (the side surface 70c) of the substrate 70. Therefore, it is possible to facility the mounting operation of the light-receiving element 51, the light-receiving element 52, and the light-receiving element 53. In addition, it is possible to facilitate optical alignment for receiving the radiation light R1, the radiation light R2, and the radiation light R3 which are output from the optical modulation element 4.

Meanwhile, the location of the anode terminal and the location of the cathode terminal in the light-receiving element 51, the location of the anode terminal and the location of the cathode terminal in the light-receiving element 52, and the location of the anode terminal and the location of the cathode terminal in the light-receiving element 53 may be switched with each other. Even in these cases, similarly, it becomes possible to suppress an increase in the installation area of the monitoring portion 7 and reduce crosstalk between the electrode group 81, the electrode group 82, and the electrode group 83. In addition, similar to the monitoring portion 7 of FIG. 5, the other end of the electrode 811, the other end of the electrode 812, the other end of the electrode 821, the other end of the electrode 822, the other end of the electrode 831, and the other end of the electrode 832 may be disposed on the same surface of the substrate 70. In this case, it is possible to electrically connect the monitoring portion 7 and external circuits on the same surface, and it becomes possible to improve working efficiency such as wire bonding. In addition, since it is possible to simplify wiring between the monitoring portion 7 and external circuits, it becomes possible to reduce the space occupied by electric lines

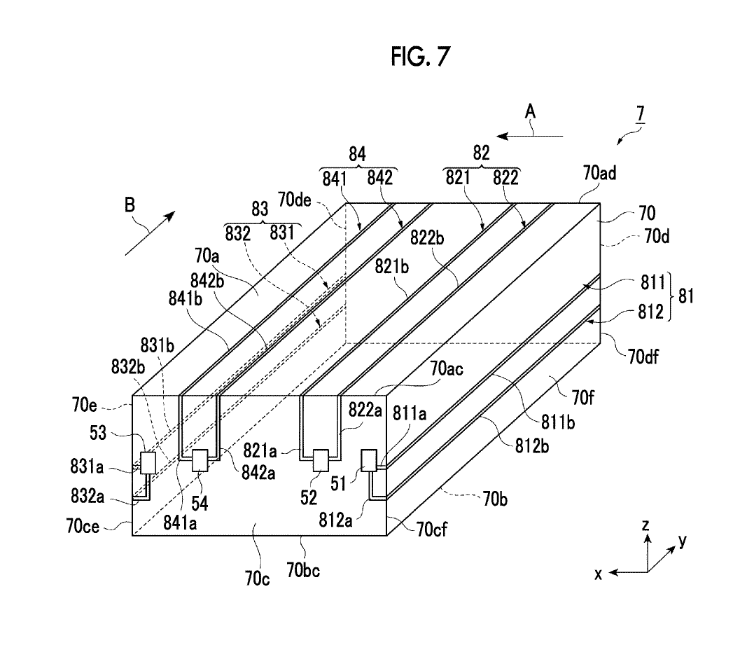

FIG. 7 is a perspective view schematically illustrating still another constitution example of the monitoring portion 7. As illustrated in FIG. 7, the monitoring portion 7 is different from the monitoring portion 7 of FIG. 6 in terms of the additional inclusion of a light-receiving element 54 and an electrode group 84. The monitoring portion 7 of FIG. 7 is used in a case in which the optical modulation element 4 further outputs radiation light R4. The light-receiving element 54 is an element for converting light signals into electrical signals and is, for example, a photo diode. The light-receiving element 54 is provided on the side surface 70c of the substrate 70. The light-receiving element 54 is disposed at locations on the side surface 70c at which the light-receiving element is capable of receiving the radiation light R4 output from the optical modulation element 4. The light-receiving element 54 receives the radiation light R4 and outputs an electrical signal E4 in accordance with the intensity of the received radiation light R4 from the anode terminal.

The light-receiving element 54 is disposed, for example, between the light-receiving element 52 and the light-receiving element 53 and is arranged in the direction A in an order of the light-receiving element 51, the light-receiving element 52, the light-receiving element 54, and the light-receiving element 53. An anode terminal of the light-receiving element 54 is provided toward, for example, the side 70cf. A cathode terminal of the light-receiving element 54 is provided toward, for example, the side 70ce.

The electrode group 84 is a set of a plurality of electrodes that are respectively connected to the light-receiving element 54. The electrode group 84 includes an electrode 841 and an electrode 842. The electrode 841 is an electrode connected to the cathode terminal of the light-receiving element 54 at one end. The electrode 841 is constituted of, for example, a metallic material such as gold (Au), silver (Ag), or copper (Cu). The width of the electrode 841 is, for example, approximately 0.05 mm to 0.5 mm. The electrode 841 is disposed across the side surface 70c and the top surface 70a of the substrate 70 and has a first portion 841a and a second portion 841b.

The first portion 841a is provided on the side surface 70c of the substrate 70 and extends in an L shape from the cathode terminal of the light-receiving element 54 up to the side 70ac. One end of the first portion 841a is connected to the cathode terminal of the light-receiving element 54. The second portion 841b is provided on the top surface 70a of the substrate 70 and extends from the side 70ac up to the side 70ad. One end of the second portion 841b is connected to the other end of the first portion 841a at the side 70ac. The other end of the second portion 841b is electrically connected to an external circuit through a wire not illustrated. The electrode 841 constituted as described above supplies certain voltage supplied from the external circuit to the cathode terminal of the light-receiving element 54.

The electrode 842 is an electrode connected to the anode terminal of the light-receiving element 54 at one end. The electrode 842 is constituted of, for example, a metallic material such as gold (Au), silver (Ag), or copper (Cu). The width of the electrode 842 is, for example, approximately 0.05 mm to 0.5 mm. The electrode 842 is disposed across the side surface 70c and the top surface 70a of the substrate 70 and has a first portion 842a and a second portion 842b.

The first portion 842a is provided on the side surface 70c of the substrate 70 and extends in an L shape from the anode terminal of the light-receiving element 54 up to the side 70ac. One end of the first portion 842a is connected to the anode terminal of the light-receiving element 54. The second portion 842b is provided on the top surface 70a of the substrate 70 and extends from the side 70ac up to the side 70ad. One end of the second portion 842b is connected to the other end of the first portion 842a at the side 70ac. The other end of the second portion 842b is electrically connected to an external circuit through a wire not illustrated. The electrode 842 constituted as described above transfers the electrical signal E4 output from the anode terminal of the light-receiving element 54 and outputs the electrical signal to the external circuit through the wire.

The electrode 841 and the electrode 842 are disposed side by side to each other. Specifically, a portion of the first portion 841a which extends in the vertical direction and a portion of the first portion 842a which extend in the vertical direction and the second portion 841b and the second portion 842b respectively extend side by side with each other. The gap between the portion of the first portion 841a which extends in the vertical direction and the portion of the first portion 842a which extend in the vertical direction and the gap between the second portion 841b and the second portion 842b are, for example, approximately 0.15 mm to 0.5 mm.

In the monitoring portion 7 of FIG. 7 as well, the same effects as in the monitoring portion 7 of FIG. 6 are exhibited. Furthermore, in the monitoring portion 7 of FIG. 7, the second portion 841b of the electrode 841 and the second portion 842b of the electrode 842 are provided on the top surface 70a of the substrate 70. As described above, when a part of the electrode group 81, a part of the electrode group 83, and a part of the electrode group 84 are disposed on mutually different surfaces, it is possible to increase the mutual distance between the electrode group 81, the electrode group 83, and the electrode group 84 without enlarging the substrate 70 compared with a case in which the electrode group 81, the electrode group 83, and the electrode group 84 are disposed on the same surface. Furthermore, although the second portion 821b of the electrode 821, the second portion 822b of the electrode 822, the second portion 841b of the electrode 841, and the second portion 842b of the electrode 842 are disposed on the same surface (the top surface 70a), when the second portion 811b of the electrode 811 and the second portion 812b of the electrode 812 are disposed on the side surface 70f, and the second portion 831b of the electrode 831 and the second portion 832b of the electrode 832 are disposed on the side surface 70e, it is possible to increase the distance between the electrode group 82 and the electrode group 84. As a result, it becomes possible to suppress an increase in the installation area of the monitoring portion 7 and reduce crosstalk between the electrode group 81, the electrode group 82, the electrode group 83, and the electrode group 84.

Meanwhile, the location of the anode terminal and the location of the cathode terminal in the light-receiving element 51, the location of the anode terminal and the location of the cathode terminal in the light-receiving element 52, the location of the anode terminal and the location of the cathode terminal in the light-receiving element 53, and the location of the anode terminal and the location of the cathode terminal in the light-receiving element 54 may be switched with each other. Even in these cases, similarly, it becomes possible to suppress an increase in the installation area of the monitoring portion 7 and reduce crosstalk between the electrode group 81, the electrode group 82, the electrode group 83, and the electrode group 84. In addition, similar to the monitoring portion 7 of FIG. 5, the other end of the electrode 811, the other end of the electrode 812, the other end of the electrode 821, the other end of the electrode 822, the other end of the electrode 831, the other end of the electrode 832, the other end of the electrode 841, and the other end of the electrode 842 may be disposed on the same surface of the substrate 70. In this case, it is possible to electrically connect the monitoring portion 7 and external circuits on the same surface, and it becomes possible to improve working efficiency such as wire bonding. In addition, since it is possible to simplify wiring between the monitoring portion 7 and external circuits, it becomes possible to reduce the space occupied by electric lines. Furthermore, a part of the electrode group 81, a part of the electrode group 82, a part of the electrode group 83, and a part of the electrode group 84 may be disposed on mutually different surfaces of the substrate 70.

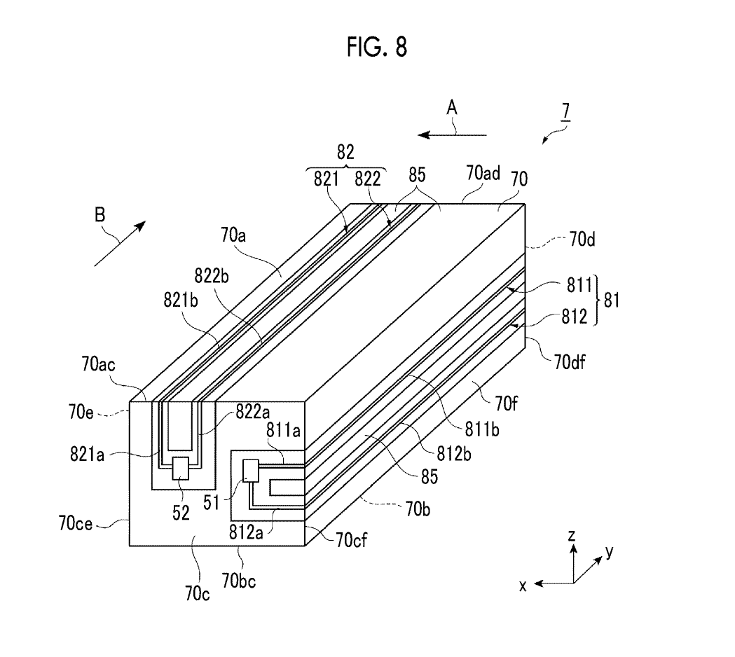

FIG. 8 is a perspective view schematically illustrating still another constitution example of the monitoring portion 7. As illustrated in FIG. 8, the monitoring portion 7 is different from the monitoring portion 7 of FIG. 6 in terms of the absence of the light-receiving element 53 and the electrode group 83 and the additional inclusion of ground electrodes 85 provided along individual electrodes.

In the monitoring portion 7 of FIG. 8, the ground electrodes 85 are disposed on both sides of individual electrodes along the electrode 811, the electrode 812, the electrode 821, and the electrode 822. That is, the ground electrodes 85 are provided away from the light-receiving element 51, the light-receiving element 52, the electrode group 81, and the electrode group 82 and cover portions on the surfaces of the monitoring portion 7 in which the light-receiving elements 51 and 52 and the electrode groups 81 and 82 are not mounted.

In the monitoring portion 7 of FIG. 8 as well, the same effects as in the monitoring portion 7 of FIG. 6 are exhibited. Furthermore, in the monitoring portion 7 of FIG. 8, the ground electrodes 85 are disposed between the respective electrodes. Therefore, it is possible to orient some of lines of electric force which are oriented from one electrode group to the other electrode group toward the ground electrodes 85. The superimposition of electromagnetic fields between electrodes adjacent to each other becomes slight, and consequently, it becomes possible to further reduce crosstalk between the electrode group 81 and the electrode group 82.

Meanwhile, the location of the anode terminal and the location of the cathode terminal in the light-receiving element 51 may be switched with each other. In addition, the location of the anode terminal and the location of the cathode terminal in the light-receiving element 52 may be switched with each other. Furthermore, it is also possible to switch the location of the anode terminal and the location of the cathode terminal in the light-receiving element 51 and switch the location of the anode terminal and the location of the cathode terminal in the light-receiving element 52. Even in these cases, similarly, it becomes possible to suppress an increase in the installation area of the monitoring portion 7 and reduce crosstalk between the electrode group 81 and the electrode group 82. In addition, similar to the monitoring portion 7 of FIG. 5, the other end of the electrode 811, the other end of the electrode 812, the other end of the electrode 821, and the other end of the electrode 822 may be disposed on the same surface of the substrate 70. In this case, it is possible to electrically connect the monitoring portion 7 and external circuits on the same surface, and it becomes possible to improve working efficiency such as wire bonding. In addition, since it is possible to simplify wiring between the monitoring portion 7 and external circuits, it becomes possible to reduce the space occupied by electric lines.

### Second Embodiment

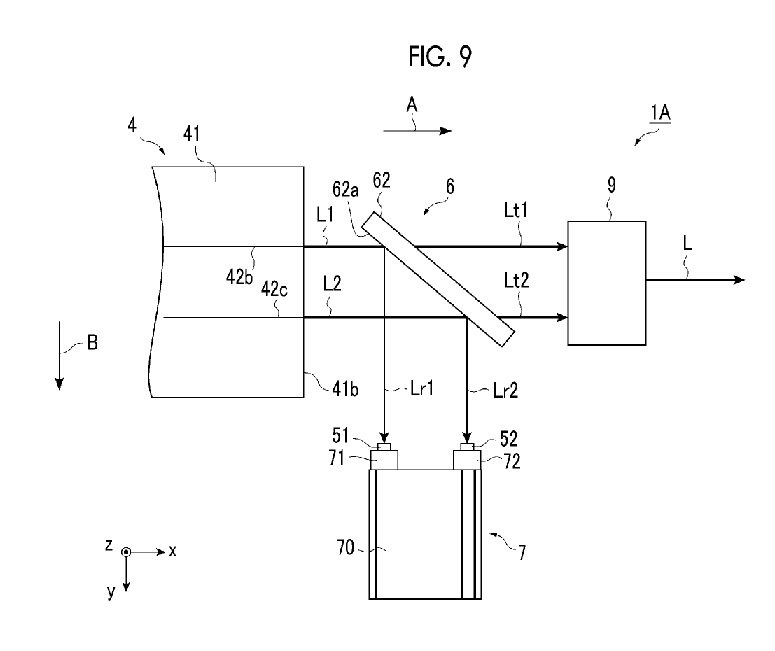

FIG. 9 is an enlarged plan view schematically illustrating a part of an optical device according to a second embodiment. As illustrated in FIG. 9, an optical device 1A is different from the optical device 1 of the first embodiment in terms of the modulation format in the optical modulation element 4 being a DP-QPSK format, the inclusion of a filter 62 instead of the supplemental member 61, and the inclusion of a polarization-combining portion 9.

The optical modulation element 4 outputs modulated light L1 and modulated light L2. The modulated light L1 is signal light having Y polarized waves. The modulated light L1 propagates in a waveguide 42b and is output in the direction A through the other end portion 41b of the optical modulation element 4. The modulated light L2 is signal light having X polarized waves. The modulated light L2 propagates in a waveguide 42c and is output in the direction A through the other end portion 41b of the optical modulation element 4.

The filter 62 reflects a predetermined fraction of incident light and transmits the remainder. The filter 62 has a surface 62a, the surface 62a faces the other end portion 41b of the optical modulation element 4, and is disposed so as to be inclined, for example, approximately 45° with respect to the light paths of the modulated light L1 and the modulated light L2. When the modulated light L1 is incident, the filter 62 reflects a part of the modulated light L1 and outputs the light as reflected light Lr1 (first output light) toward the light-receiving element 51 in the monitoring portion 7 and transmits the remaining part of the modulated light L1 and outputs the light as transmitted light Lt1 to the polarization-combining portion 9. When the modulated light L2 is incident, the filter 62 reflects a part of the modulated light L2 and outputs the light as reflected light Lr2 (second output light) toward the light-receiving element 52 in the monitoring portion 7 and transmits the remaining part of the modulated light L2 and outputs the light as transmitted light Lt2 to the polarization-combining portion 9. Meanwhile, here, the inclination angle of the filter 62 has been described as 45°, but may be any angles other than 45° as necessary.

The polarization-combining portion 9 combines a plurality of modulated light output from the optical modulation element 4. The polarization-combining portion 9 is an element that changes the light path of incident light in accordance with the polarization direction and is constituted of, for example, birefringence crystals such as rutile and yttrium vanadate (YVO₄). The polarization-combining portion 9 combines the transmitted light Lt1 and the transmitted light Lt2 which has passed through the filter 62 and outputs the combined light L to the optical fiber F2. In addition, in the polarization-combining portion 9, a polarization beam splitter (PBS) may be used.

The monitoring portion 7 monitors the light intensities of the reflected light Lr1 and the reflected light Lr2 which are output through the filter 62. The monitoring portion 7 receives the reflected light Lr1 and the reflected light Lr2 and outputs electrical signals in accordance with the light intensities of the reflected light Lr1 and the reflected light Lr2 which have been received by the monitoring portion to a bias control portion (not illustrated) which is an external circuit. As the monitoring portion 7, the wiring device exemplified in the first embodiment may be used.

In the optical device 1A as well, the same effects as in the optical device 1 are exhibited. Meanwhile, the optical device 1A is not limited to the constitution of FIG. 9. The normal direction to the incidence surface of the transmitted light Lt1 and the transmitted light Lt2 in the polarization-combining portion 9 and the normal direction to the exit surface of light L in the polarization-combining portion 9 may be inclined with respect to the light axes of the transmitted light Lt1 and the transmitted light Lt2. In this case, the monitoring portion 7 may monitor a part of the transmitted light Lt1 and the transmitted light Lt2 which have been reflected on the incidence surface or the exit surface of the polarization-combining portion 9. In addition, reflectivity may be adjusted by providing a reflection film on the incidence surface or the exit surface. According to the above-described constitution, it is possible to carry out monitoring using a constitution including less components without using separate filters.

### Third Embodiment

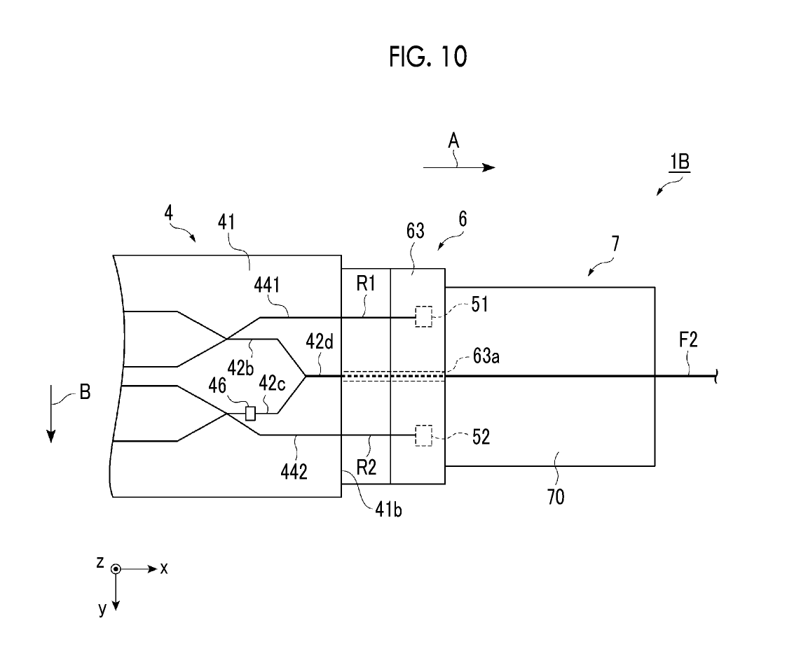

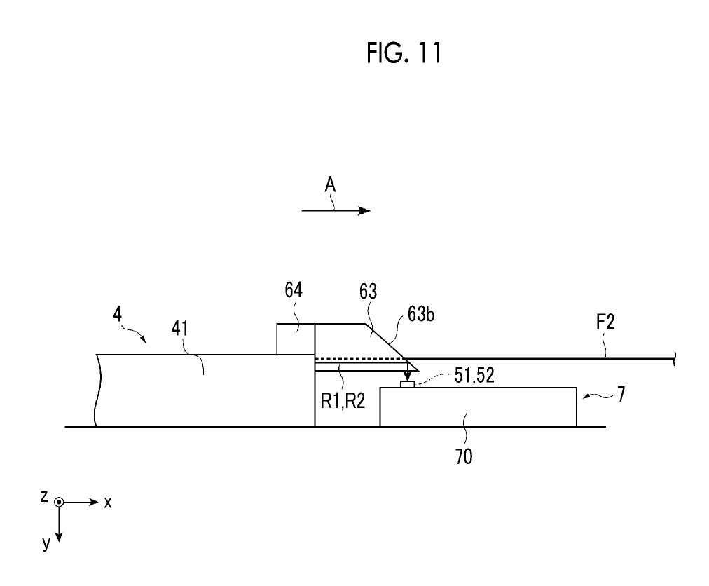

FIG. 10 is an enlarged plan view schematically illustrating a part of an optical device according to a third embodiment. FIG. 11 is a side view of the optical device of FIG. 10. As illustrated in FIGS. 10 and 11, an optical device 1B is different from the optical device 1 of the first embodiment in terms of the including a supplemental member 63 instead of the supplemental member 61 and the disposition of the monitoring portion 7.

The supplemental member 63 is a member for holding the optical fiber F2 and reflecting the radiation light R1 and the radiation light R2 which have been output from the optical modulation element 4 downwards. The supplemental member 63 has a shape of a column extending in the direction B and is constituted of an optical member transmitting the radiation light R1 and the radiation light R2. Examples of the optical member include BK7, borosilicate glass, silica glass, silicon, and the like. The supplemental member 63 has a through hole 63a passing through the supplemental member 63 in the direction A. The supplemental member 63 holds the optical fiber F2 so that the optical fiber F2 is inserted into the through hole 63a and the output waveguide 42d in the optical waveguide 42 is optically coupled with the optical fiber F2. The supplemental member 63 has a reflection surface 63b. The reflection surface 63b is inclined, for example, approximately 45° with respect to the direction A and reflects the radiation light R1 and the radiation light R2 which have been output from the optical modulation element 4 downwards. Meanwhile, the supplemental member 63 may have a V-shaped groove or slit instead of the through hole 63a.

The front end of the supplemental member 63 is fixed to the other end portion 41b of the substrate 41. The front end of the supplemental member 63 is adhered to, for example, the other end portion 41b of the substrate 41. A supplemental member 64 may be provided on the top surface of the other end portion 41b of the substrate 41. The supplemental member 64 is a member for supplementing the adhesion between the other end portion 41b of the substrate 41 and the supplemental member 63 and is fixed to the top surface of the substrate 41. The front end of the supplemental member 63 is adhered to the supplemental member 64.

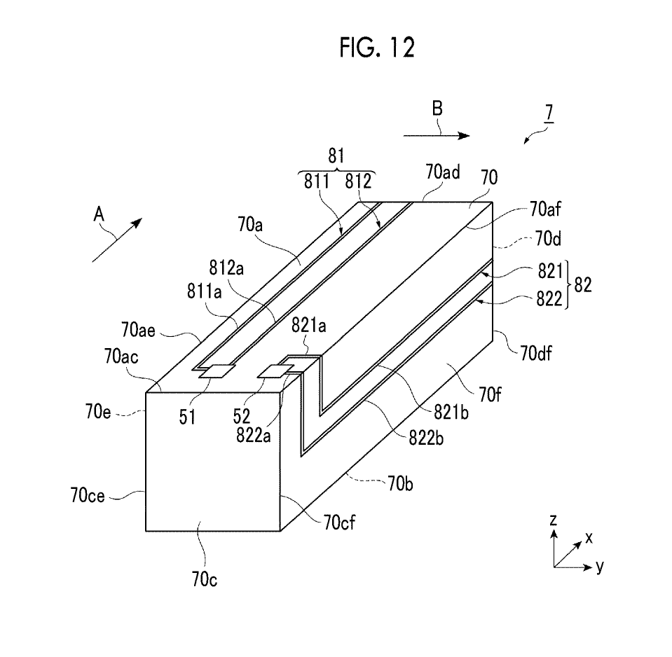

FIG. 12 is a perspective view schematically illustrating a constitution example of the monitoring portion 7 in the optical device 1B. As illustrated in FIGS. 11 and 12, the monitoring portion 7 is installed in the package case 10 so that the light-receiving element 51 and the light-receiving element 52 are located below the supplemental member 63. When specifically described, in the monitoring portion 7 in the optical device 1B, the substrate 70 has a shape of a column extending in the direction A. The light-receiving element 51 is provided in the front part of the top surface 70a of the substrate 70. The light-receiving element 51 is disposed at a location on the top surface 70a at which the light-receiving element is capable of receiving the radiation light R1 which has been reflected by the supplemental member 63. The anode terminal of the light-receiving element 51 is provided toward, for example, a side 70ae which is the boundary between the top surface 70a and the side surface 70e. The cathode terminal of the light-receiving element 51 is provided toward, for example, the side 70ad. The light-receiving element 52 is provided in the front part of the top surface 70a of the substrate 70. The light-receiving element 52 is disposed at a location on the top surface 70a at which the light-receiving element is capable of receiving the radiation light R2 which has been reflected by the supplemental member 63. The anode terminal of the light-receiving element 52 is provided toward, for example, the side 70af. The cathode terminal of the light-receiving element 52 is provided toward, for example, the side 70ad. The light-receiving element 51 and the light-receiving element 52 are arranged in the direction B in this order.

The electrode 811 is disposed on the top surface 70a of the substrate 70 and has the first portion 811a. The first portion 811a is provided on the top surface 70a of the substrate 70 and extends in an L shape from the anode terminal of the light-receiving element 51 up to the side 70ad. One end of the first portion 811a is connected to the anode terminal of the light-receiving element 51. The other end of the first portion 811a is electrically connected to an external circuit through a wire not illustrated. The electrode 812 is disposed on the top surface 70a of the substrate 70 and has the first portion 812a. The first portion 812a is provided on the top surface 70a of the substrate 70 and extends from the cathode terminal of the light-receiving element 51 up to the side 70ad. One end of the first portion 812a is connected to the cathode terminal of the light-receiving element 51. The other end of the first portion 812a is electrically connected to an external circuit through a wire not illustrated.

The electrode 811 and the electrode 812 are disposed side by side to each other. Specifically, a portion of the first portion 811a which extends in the direction A and the first portion 812a respectively extend side by side with each other, and the gap therebetween is, for example, approximately 0.15 mm to 0.5 mm.

The electrode 821 is disposed across the top surface 70a and the side surface 70f of the substrate 70 and has the first portion 821a and the second portion 821b. The first portion 821a is provided on the top surface 70a of the substrate 70 and extends in an L shape from the cathode terminal of the light-receiving element 52 up to the side 70af. One end of the first portion 821a is connected to the cathode terminal of the light-receiving element 52. The second portion 821b is provided on the side surface 70f of the substrate 70 and extends in an L shape from the side 70af up to the side 70df. One end of the second portion 821b is connected to the other end of the first portion 821a at the side 70af. The other end of the second portion 821b is electrically connected to an external circuit through a wire not illustrated.

The electrode 822 is disposed across the top surface 70a and the side surface 70f of the substrate 70 and has the first portion 822a and the second portion 822b. The first portion 822a is provided on the top surface 70a of the substrate 70 and extends from the anode terminal of the light-receiving element 52 up to the side 70af. One end of the first portion 822a is connected to the anode terminal of the light-receiving element 52. The second portion 822b is provided on the side surface 70f of the substrate 70 and extends in an L shape from the side 70af up to the side 70df. One end of the second portion 822b is connected to the other end of the first portion 822a at the side 70af. The other end of the second portion 822b is electrically connected to an external circuit through a wire not illustrated.

The electrode 821 and the electrode 822 are disposed side by side to each other. Specifically, a portion of the first portion 821a which extends in the direction B and the first portion 822a and the second portion 821b and the second portion 822b respectively extend side by side with each other. The gap between the portion of the first portion 821a which extends in the direction B and the first portion 822a and the gap between the second portion 821b and the second portion 822b are, for example, approximately 0.15 mm to 0.5 mm.

In the optical device 1B as well, the same effects as in the optical device 1 are exhibited. Furthermore, in the optical device 1B, since the monitoring portion 7 is disposed below the optical fiber F2, it is possible to further reduce the installation area of the monitoring portion 7. In addition, compared with a constitution in which light is reflected in a side surface direction of the substrate 41 (direction B) as in the optical device 1 of the first embodiment, it is possible to reduce the superimposition of the radiation light R1 and the radiation light R2, and it becomes possible to improve the monitoring accuracy.

In the monitoring portion 7 of FIG. 12, the electrode 811 and the electrode 812 are provided on the top surface 70a of the substrate 70, and the second portion 821b of the electrode 821 and the second portion 822b of the electrode 822 are provided on the side surface 70f of the substrate 70. As described above, when the electrode group 81 and a part of the electrode group 82 are disposed on mutually different surfaces, it is possible to increase the distance between the electrode group 81 and the electrode group 82 without enlarging the substrate 70 compared with a case in which the electrode group 81 and the electrode group 82 are disposed on the same surface. As a result, it becomes possible to suppress an increase in the installation area of the monitoring portion 7 and reduce crosstalk between the electrode group 81 and the electrode group 82.

In addition, in the monitoring portion 7 of FIG. 12, the light-receiving element 51 and the light-receiving element 52 are provided on the same surface (the top surface 70a) of the substrate 70. Therefore, it is possible to facility the mounting operation of the light-receiving element 51 and the light-receiving element 52. In addition, it is possible to facilitate optical alignment for receiving the radiation light R1 and the radiation light R2 which have been reflected by the supplemental member 63.

Meanwhile, the location of the anode terminal and the location of the cathode terminal in the light-receiving element 51 may be switched with each other. In addition, the location of the anode terminal and the location of the cathode terminal in the light-receiving element 52 may be switched with each other. Furthermore, it is also possible to switch the location of the anode terminal and the location of the cathode terminal in the light-receiving element 51 and switch the location of the anode terminal and the location of the cathode terminal in the light-receiving element 52. Even in these cases, similarly, it becomes possible to suppress an increase in the installation area of the monitoring portion 7 and reduce crosstalk between the electrode group 81 and the electrode group 82. In addition, similar to the monitoring portion 7 of FIG. 5, the other end of the electrode 811, the other end of the electrode 812, the other end of the electrode 821, and the other end of the electrode 822 may be disposed on the same surface of the substrate 70. In this case, it is possible to electrically connect the monitoring portion 7 and external circuits on the same surface, and it becomes possible to improve working efficiency such as wire bonding. In addition, since it is possible to simplify wiring between the monitoring portion 7 and external circuits, it becomes possible to reduce the space occupied by electric lines.

Meanwhile, the optical device according to the present invention is not limited to the above-described embodiments. For example, the optical device 1 is not limited to optical modulators and may be other optical devices such as receiver modules that receive modulated light. In addition, the optical modulation element 4 is preferably a light element that outputs a plurality of output light.

In the above-described embodiments, since the electrodes connected to the cathode terminals of the light-receiving elements 51, 52, 53, and 54 are not grounded, crosstalk between the electrode groups 81, 82, 83, and 84 is reduced. The electrodes connected to the cathode terminals of the light-receiving elements 51, 52, 53, and 54 may be grounded. In this case, it becomes possible to reduce crosstalk between the electrodes connected to the anode terminals of the light-receiving elements 51, 52, 53, and 54.

In addition, a plurality of electrodes constituting the respective electrode groups may have lengths that are substantially equal to each other. In this case, it is possible to reduce the deterioration of signals in the respective electrodes. In addition, a plurality of electrodes constituting the respective electrode groups may extend in parallel with each other. In this case, it is possible to further suppress unnecessary electric field emission and the coupling of signals between electrodes by placing electrode lines for the light-receiving elements in parallel. Therefore, it is possible to further reduce the deterioration of the high-frequency characteristics of electrical signals propagating through a plurality of electrodes constituting the respective electrode groups.

The substrate 70 is not limited to quadratic prisms and may be a polyhedron. Meanwhile, the dimensions of the substrate 70, the sub substrate 71, and the sub substrate 72 are not limited to the dimensions described in the above-described embodiments. The dimensions of the substrate 70, the sub substrate 71, and the sub substrate 72 may be appropriately determined depending on the dimensions inside the package case 10.

### REFERENCE SIGNS LIST

1, 1A, 1B . . . optical device, 4 . . . optical modulation element (light element), 7 . . . monitoring portion, 51 . . . light-receiving element (first light-receiving portion), 52 . . . light-receiving element (second light-receiving portion), 53 . . . light-receiving element (third light-receiving portion), 70 . . . substrate, 70a . . . top surface, 70b . . . bottom surface, 70c . . . side surface, 70d . . . side surface, 70e . . . side surface, 70f . . . side surface, 81 . . . electrode group (first electrode group), 82 . . . electrode group (second electrode group), 83 . . . electrode group (third electrode group), 85 . . . ground electrode, 811 . . . electrode (third electrode), 812 . . . electrode (first electrode), 821 . . . electrode (second electrode), Lr1 . . . reflected light (first output light), Lr2 . . . reflected light (second output light), R1 . . . radiation light (first output light), R2 . . . radiation light (second output light), R3 . . . radiation light (third output light)

1-6. (canceled)

7. A optical device comprising:
a light element that outputs first output light and second output light;
a first light-receiving portion that converts the first output light into a first electrical signal;
a second light-receiving portion that converts the second output light into a second electrical signal;
a substrate having a plurality of surfaces;
a first electrode which is provided on the substrate and of which one end is connected to the first light-receiving portion; and
a second electrode which is provided on the substrate and of which one end is connected to the second light-receiving portion,
wherein a part of the first electrode is disposed on a surface different from a surface on which the second electrode is disposed,
the other end of the first electrode and the other end of the second electrode are disposed on the same surface out of the plurality of surfaces, and
the other end of the first electrode and the other end of the second electrode are respectively connected to an external circuit through a wire.

8. The optical device according to claim 7, further comprising:
a supplemental member that holds an optical fiber and reflects downwards the first output light and the second output light which are output from the light element; and
a package case that stores the light element, the first light-receiving portion, the second light-receiving portion, the substrate, and the supplemental member,
wherein the light element includes an optical waveguide that is optically coupled to the optical fiber, and
the first light-receiving portion and the second light-receiving portion are disposed below the supplemental member.

9. The optical device according to claim 7, further comprising:
a first electrode group which includes the first electrode and includes electrodes that are respectively connected to the first light-receiving portion; and
a second electrode group which includes the second electrode and includes electrodes that are respectively connected to the second light-receiving portion,
wherein a part of the first electrode group is disposed on a surface different from a surface on which the second electrode group is disposed.

10. The optical device according to claim 9, further comprising:
a third light-receiving portion that converts third output light into a third electrical signal; and
a third electrode group in which electrodes are respectively connected to the third light-receiving portion,
wherein the light element further outputs the third output light, and
a part of the first electrode group, a part of the second electrode group, and a part of the third electrode group are disposed on mutually different surfaces.

11. The optical device according to claim 9,
wherein the first electrode group further includes a third electrode, and
a part of the first electrode and a part of the third electrode are disposed side by side to each other.

12. The optical device according to claim 7,
wherein the first light-receiving portion and the second light-receiving portion are provided on the same surface out of a plurality of the surfaces of the substrate.

13. The optical device according to claim 7, further comprising:
a ground electrode which is disposed between the first electrode and the second electrode.

14. The optical device according to claim 7,
wherein the light element is an optical modulation element, and
the light element includes a plurality of Mach-Zehnder portions.
